(19) United States
(12) Patent Application Publication
(10) Pub. No.: US 2024/0310720 A1
(43) Pub. Date: Sep. 19, 2024

(54) OVERLAY CORRECTION METHOD AND SEMICONDUCTOR DEVICE MANUFACTURING METHOD COMPRISING THE OVERLAY CORRECTION METHOD

(71) Applicant: Samsung Electronics Co., Ltd., Suwon-si (KR)

(72) Inventors: Jaeil Lee, Suwon-si (KR); Kyoungcho Na, Suwon-si (KR)

(21) Appl. No.: 18/535,149

(22) Filed: Dec. 11, 2023

(30) Foreign Application Priority Data
Mar. 13, 2023 (KR) 10-2023-0032816

(51) Int. Cl. G03F 1/70

(52) U.S. Cl. CPC G03F 1/70; G03F 7/2004

(57) ABSTRACT

An overlay correction method capable of accurately measuring and correcting higher-order components of an overlay of a first layer in which a pattern is first formed on a semiconductor substrate, and improving matching with exposure equipment in a subsequent exposure process is disclosed. The overlay correction method includes forming a first overlay mark on a first layer on which a pattern is initially formed on a semiconductor substrate, performing an absolute measurement on the first overlay mark, and correcting an overlay of the first layer based on the absolute measurement. The absolute measurement is a measurement method based on a fixed position of exposure equipment used to form the first overlay mark.

### CROSS-REFERENCE TO RELATED APPLICATION

This application is based on and claims priority under 35 U.S.C. § 119 to Korean Patent Application No. 10-2023-0032816, filed on Mar. 13, 2023, in the Korean Intellectual Property Office, the disclosure of which is incorporated by reference herein in its entirety.

### BACKGROUND

Embodiments of the inventive concept relates to an overlay correction method, and more particularly, to an overlay correction method of correcting an overlay of a first layer in which a pattern is first formed on a semiconductor substrate, and a semiconductor device manufacturing method including the overlay correction method.

Line widths in semiconductor circuits have become finer, and accordingly, use of an exposure process using extreme ultraviolet (EUV) equipment has increased. For example, patterns of a plurality of layers are formed in one chip by using a combination of deep ultraviolet (DUV) equipment with EUV equipment. The DUV equipment and the EUV equipment use light sources of different wavelengths and also differ from each other in terms of a wafer stage, a reticle, a slit, an optical system, etc. Due to the differences between the DUV equipment and the EUV equipment with respect to when they are used in combination with each other, an overlay misalignment may occur when a fine pattern is formed.

### SUMMARY

Embodiments of the inventive concept provide an overlay correction method capable of accurately measuring and correcting higher-order components of an overlay of a first layer in which a pattern is first formed on a semiconductor substrate and improving matching with exposure equipment in a subsequent exposure process.

In addition, the problems to be solved by embodiments of the inventive concept are not limited to the aforementioned problems, and other problems may be clearly understood by those skilled in the art from the following description.

According to an aspect of the inventive concept, there is provided an overlay correction method including forming a first overlay mark on a first layer on which a pattern is initially formed on a semiconductor substrate, performing an absolute measurement on the first overlay mark, and correcting an overlay of the first layer based on the absolute measurement, wherein the absolute measurement is a measurement method based on a fixed position of exposure equipment used to form the first overlay mark.

According to another aspect of the inventive concept, there is provided an overlay correction method including forming, by using first exposure equipment, a first overlay mark on a first layer on which a pattern is initially formed on a semiconductor substrate, performing an absolute measurement on the first overlay mark, calculating components of an overlay of the first layer based on the absolute measurement, determining whether the components of the overlay of the first layer satisfy a set criterion, when the set criterion is not satisfied, inputting the components of the overlay of the first layer to the first exposure equipment, and re-forming the first overlay mark on the semiconductor substrate by using the first exposure equipment. The first overlay mark includes an outer mark and an inner mark formed on the first layer, and, in the performing of the absolute measurement, the absolute measurement is performed on each of the outer mark and the inner mark separately.

According to another aspect of the inventive concept, there is provided a semiconductor device manufacturing method including forming, by using first exposure equipment, a first overlay mark on a first layer on which a pattern is initially formed on a semiconductor substrate, performing an absolute measurement on the first overlay mark, calculating an overlay of the first layer based on the absolute measurement, determining whether the overlay of the first layer satisfies a set criterion, and, when the set criterion is satisfied, performing a subsequent semiconductor process. When the set criterion is not satisfied, data about the overlay of the first layer is input to the first exposure equipment, the method further comprising re-forming the first overlay mark. The absolute measurement is a measurement method based on a fixed position of the first exposure equipment.

### BRIEF DESCRIPTION OF THE DRAWINGS

Example embodiments of the inventive concept will be more clearly understood from the following detailed description taken in conjunction with the accompanying drawings in which:

FIG. 1A is a schematic flowchart of an overlay correction method according to an embodiment;

FIG. 1B is a flowchart illustrating, in more detail, an operation of correcting the overlay of a first layer in the overlay correction method of FIG. 1A;

FIG. 2 includes plan views and cross-sectional views illustrating the concept of overlay measurement using overlay marks;

FIGS. 3A and 3B are conceptual diagrams that illustrate a relative measurement and an absolute measurement used in overlay measurement in the overlay correction method of FIG. 1A;

FIGS. 4A and 4B are plan views of a box in box (BIB) mark and an advanced image metrology (AIM) mark used in the overlay measurement in the overlay correction method of FIG. 1A;

FIG. 5A is a plan view of BIB marks disposed in one shot of a first layer in which a pattern is initially formed on a semiconductor substrate, and FIG. 5B is a plan view of BIB marks disposed in shots adjacent to the first layer;

FIG. 6A is a plan view of AIM marks disposed in one shot of a first layer in which a pattern is initially formed on a semiconductor substrate, and FIG. 6B is a plan view of AIM marks disposed in shots adjacent to the first layer;

FIGS. 7A through 7H are conceptual views that illustrate components of a stitch overlay that may be calculated through relative measurement using shots adjacent to each other in the x direction;

FIGS. 8A through 8H are conceptual views that illustrate components of a stitch overlay that may be calculated through relative measurement using shots adjacent to each other in the y direction;

FIGS. 9A through 9D are conceptual views that illustrate representative components that may not be calculated through relative measurement using the shots adjacent to each other in the x direction and the y direction;

FIGS. 10A and 10B are conceptual diagrams illustrating matching between exposure equipment generated in an overlay correction method using relative measurement according to a comparative example and the overlay correction method using absolute measurement according to an example embodiment;

FIG. 11A is a conceptual diagram that illustrates a semiconductor device manufacturing method including an overlay correction method according to an embodiment; and

FIG. 11B is a flowchart of the semiconductor device manufacturing method of FIG. 11A.

### DETAILED DESCRIPTION OF THE EMBODIMENTS

Embodiments will now be described more fully with reference to the accompanying drawings. In the accompanying drawings, like reference numerals may refer to like elements, and repeated descriptions of the like elements will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. In the present specification, although terms such as first and second are used to describe various elements or components, it goes without saying that these elements or components are not limited by these terms. These terms are only used to distinguish a single element or component from other elements or components. Therefore, it goes without saying that a first element or component referred to below may be a second element or component within the technical idea of embodiments of the present inventive concept.

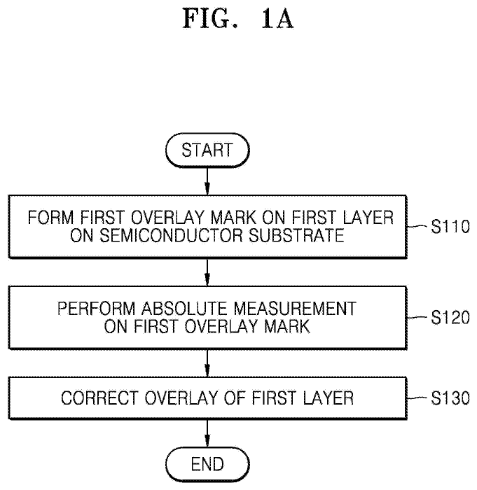

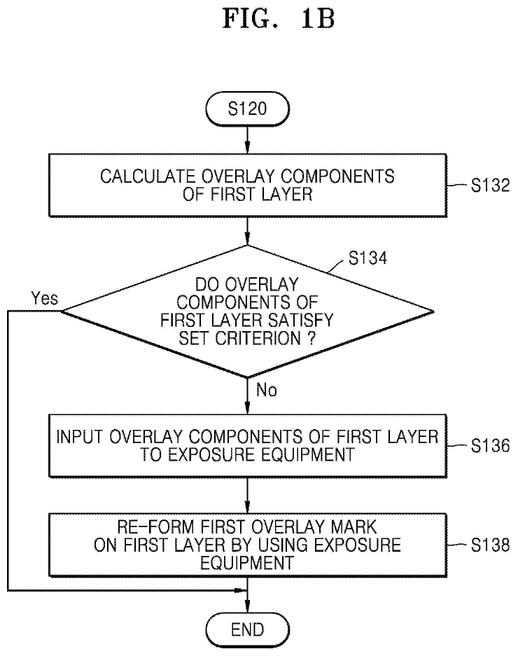

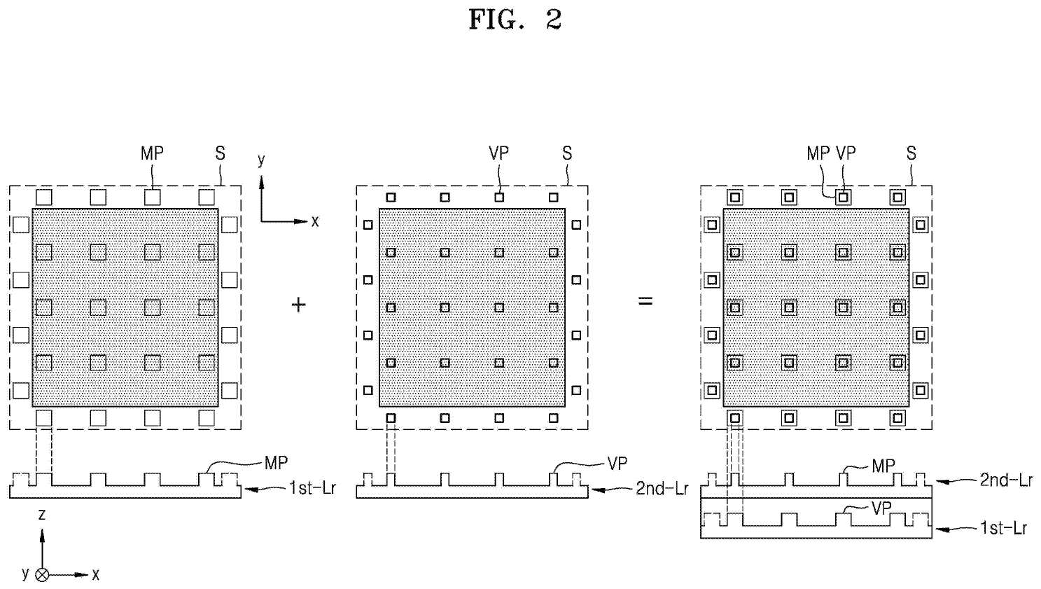

FIG. 1A is a schematic flowchart of an overlay correction method according to an embodiment, FIG. 1B is a flowchart illustrating, in more detail, an operation of correcting the overlay of a first layer in the overlay correction method of FIG. 1A, and FIG. 2 includes plan views and cross-sectional views illustrating the concept of overlay measurement using overlay marks.

Referring to FIGS. 1A through 2, in the overlay correction method according to the present embodiment, first, a first overlay mark is formed on a first layer of a semiconductor substrate (S110). The first layer may refer to a layer for first patterning a circuit on a semiconductor substrate, such as a wafer. In other words, other patterns may not be formed in the semiconductor substrate under the first layer. An overlay mark is also referred to as an overlay key, and may refer to a pattern formed for overlay measurement. In general, overlay may refer to a degree of misalignment between a previous processing step and a current processing step. The overlay is also referred to as an ‘overlay error’. Hereinafter, for convenience of description, the ‘overlay error’ will be commonly referred to as the overlay.

After the formation of the first overlay mark, an absolute measurement may be performed on the first overlay mark on the first layer (S120). Through measurement of the first overlay mark, an overlay of the first layer may be obtained. In general, an overlay may be obtained by measuring an overlay mark created on a scribe lane or measure the degree of misalignment or shift between patterns of a previous processing step and a current processing step on a cell array and quantifying a result of the measurement through calculation. In the overlay correction method according to the present embodiment, the overlay of the first layer may be obtained by performing absolute measurement on the first overlay mark of the first layer.

FIG. 2 illustrates an overlay mark, for example, a box in box (BIB) mark, used for general overlay measurement between a lower layer and an upper layer. The overlay mark used for overlay measurement is not limited to a BIB mark. For example, an advanced image metrology (AIM) mark may be used for overlay measurement. For reference, overlay marks used for overlay measurement may be largely classified into an image based overlay (IBO) mark and a diffraction based overlay (DBO) mark. The BIB mark and the AIM mark may belong to the IBO mark. As can be seen from the term, the DBO mark may measure the overlay by using diffraction characteristics of light.

Describing the overlay measurement in more detail, as shown on the left side of FIG. 2, a main pattern MP of an overlay mark may be formed in a first layer 1st-Lr of a previous processing step, and, as shown in the middle of FIG. 2, a vernier pattern VP of an overlay mark may be formed in a second layer 2nd-Lr of a current processing step. Then, as shown on the right side of FIG. 2, a degree of misalignment between the main pattern MP of the first layer 1st-Lr and the venier pattern VP of the second layer 2nd-Lr may be measured through a measuring device to measure an overlay.

The main pattern MP and the vernier pattern VP may also be referred to as an outer mark and an inner mark due to their sizes and locations. The overlay mark may be formed on a scribe lanes of inner and outer portions of a shot S. In FIG. 2, a dotted line square may correspond to one shot S. A non-hatched portion in a rectangular ring shape in the outer portion of the shot S may correspond to a scribe lane of the outer portion of the shot S. The inner portion of the shot S is a hatched rectangular portion, and the scribe lane of the inner portion is not shown. The shot S may be defined as a pattern on a reticle or pattern information reduced and projected once onto a wafer in an exposure process. In the exposure process, one shot S may correspond to an area irradiated while being scanned by light in a y direction through a slit extending in an x direction.

In addition, in FIG. 2, only main patterns MP are disposed in the first layer 1st-Lr, and only vernier patterns VP are disposed in the second layer 2nd-Lr. However, this may correspond to a shape simplified to illustrate overlay measurement. In practice, main patterns MP and vernier patterns VP may be formed together in one layer. For example, main patterns MP of the first layer 1st-Lr may be used together with vernier patterns VP of the second layer 2nd-Lr for overlay measurement of the second layer 2nd-Lr, and vernier patterns VP of the first layer 1st-Lr may be used together with vernier patterns of a lower layer of a previous processing step for overlay measurement of the first layer 1st-Lr. Main patterns of the second layer 2nd-Lr may be used for overlay measurement of an upper layer of a subsequent processing step, together with vernier patterns of the upper layer.

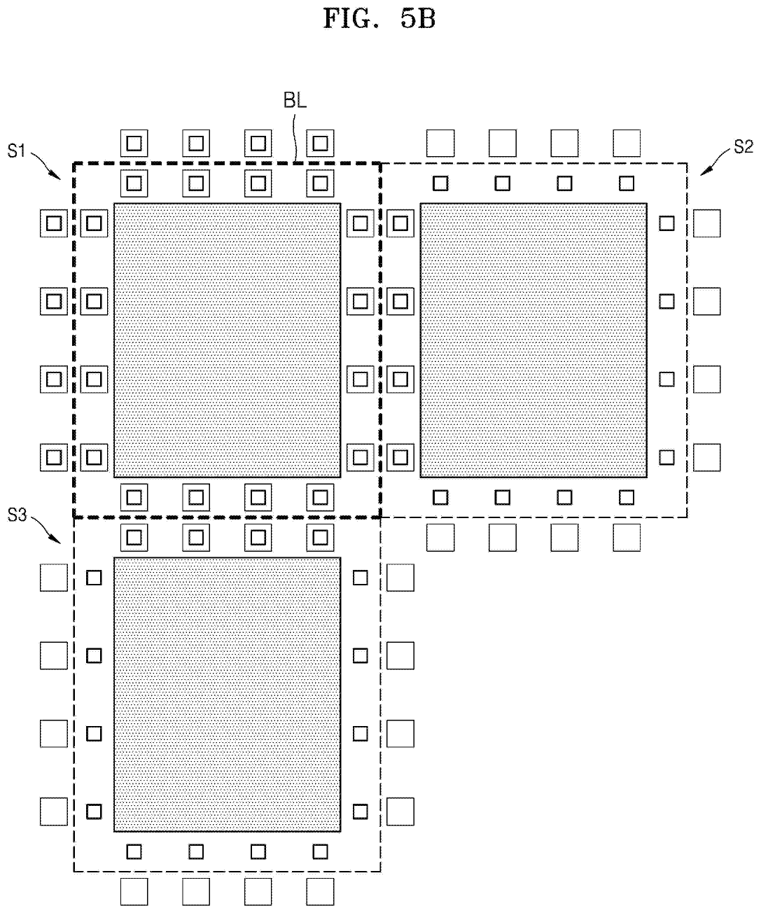

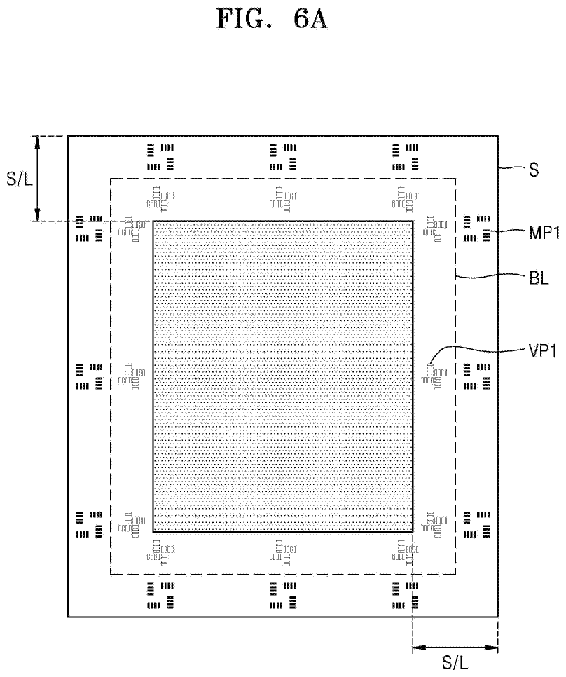

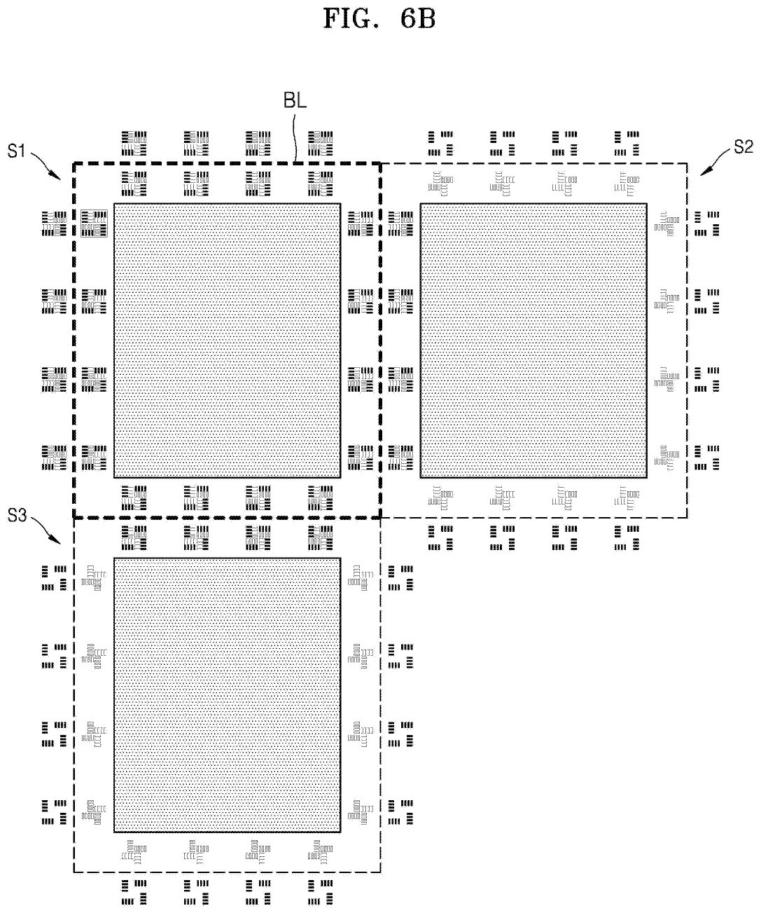

The overlay of the first layer is referred to as a stitch overlay. In the case of the first layer, because there are no previous layers, overlay marks on the scribe lanes of respective outer portions of adjacent shots are formed to overlap each other for overlay measurement, and an overlay of the first layer may be obtained through measurement of these overlay marks. Overlay marks for stitch overlay measurement will be described in more detail in the description of FIGS. 5A through 6B.

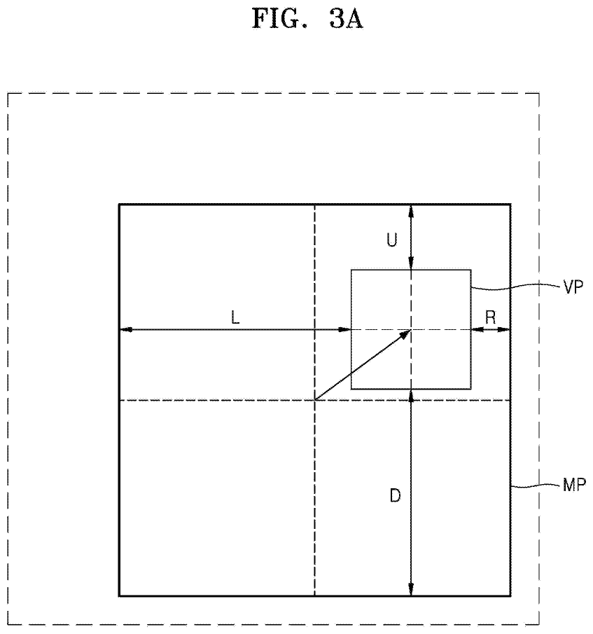

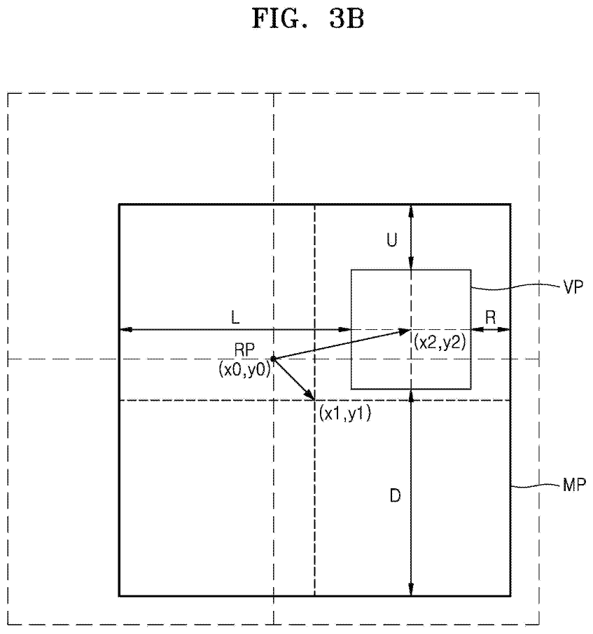

In the overlay correction method according to the present embodiment, an absolute measurement method may be used to measure the overlay of the first layer. Relative measurement may also be used together with absolute measurement for measurement of the overlay of the first layer. Absolute measurement may refer to measurement based on a fixed position. The fixed position does not change in an exposure process and may correspond to the origin of absolute coordinates. For example, the fixed position may be a reference position on a wafer stage, separate from a semiconductor substrate on which an overlay mark is formed. Meanwhile, relative measurement, which is a concept opposite to absolute measurement, may refer to measurement based on a selected position. The selected position may change in an exposure process. For example, the selected position may be any one point in a semiconductor substrate where an overlay mark is formed. Consequently, a relative measurement may refer to the measurement of only a relative position between the selected position and a measurement position. Relative measurement and absolute measurement will be described in more detail in the description of FIGS. 3A and 3B.

Referring back to FIG. 1, after the absolute measurement on the first overlay mark, an overlay of the first layer is corrected (S130). Correcting the overlay may refer to correcting the overlay so that the overlay is minimized or removed by inputting data of the overlay obtained by performing absolute measurement on the first overlay mark to corresponding exposure equipment.

Referring to FIG. 1B, continuing the description in more detail, in correcting the overlay of the first layer, overlay components of the first layer are calculated based on absolute measurement and/or relative measurement (S132). The overlay components may be referred to as overlay parameters, and may be roughly classified into a component moved from an expected position in the x direction, namely, a first overlay parameter related to dx, and a component moved from the expected position in the y direction, namely, a second overlay parameter related to dy. The x direction may correspond to an extension direction of a slit in an exposure process, and the y direction may correspond to a scan direction perpendicular to the x direction. In the following, among overlay parameters represented by K1 through K20, odd-numbered overlay parameters may belong to the first overlay parameter, and even-numbered overlay parameters may belong to the second overlay parameter.

As for the overlay parameters, first, there are overlay parameters K1 through K6 of linear components. When expressed as dx and dy, dx=K1, dx=K3*x, dx=K5*y, dy=K2, dy=K4*y, and dy=K6*x. Next, there are overlay parameters K7 through K12 of 2^{nd}-order components. When expressed as dx and dy, dx=K7*x², dx=K9*xy, dx=K11*y², dy=K8*y², dy=K10*yx, and dy=K12*x². There are overlay parameters K13 through K20 of 3^{rd} order components. When expressed as dx and dy, dx=K13*x³, dx=K15*x²y, dx=K17*xy², dx=K19*y³, dy=K14*y³, dy=K16*y²x, dy=K18*yx², and dy=K20*x³. Parameters of 4^{th}-order or greater components also exist, but a description thereof is omitted. A 2^{nd}-order or greater component among the overlay parameters is referred to as a high-order component.

In the overlay correction method according to the present embodiment, a 2^{nd}-order or greater component of the overlay may be calculated by performing absolute measurement on the first overlay mark of the first layer. For reference, the overlay of the first layer, that is, a stitch overlay, is generally calculated through relative measurement. However, because the relative measurement is measurement with respect to the first overlay mark between adjacent shots in the first layer, accurately calculating the 2^{nd}-order or greater components except for several linear components may be difficult or impossible because of the characteristics of the relative measurement.

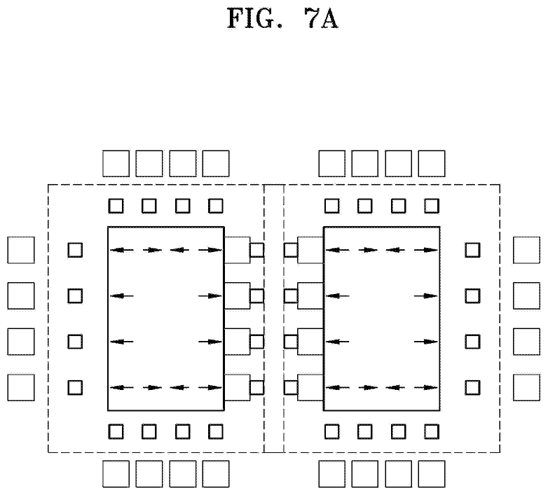

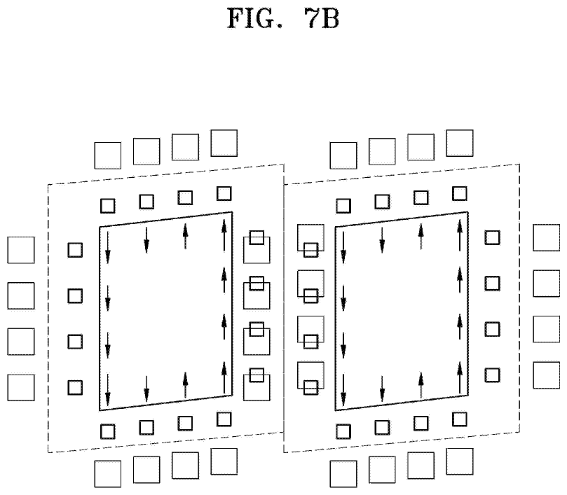

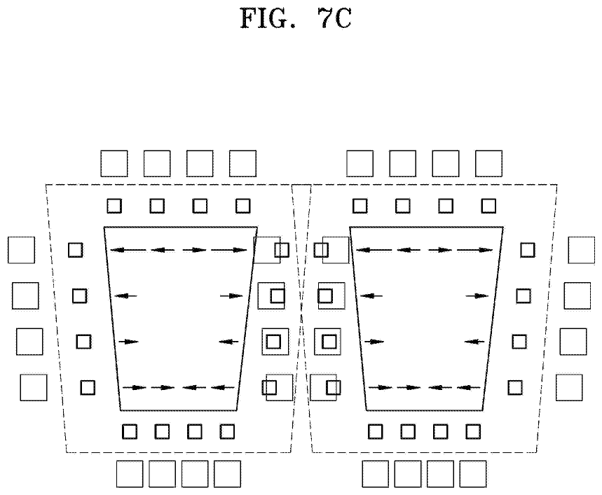

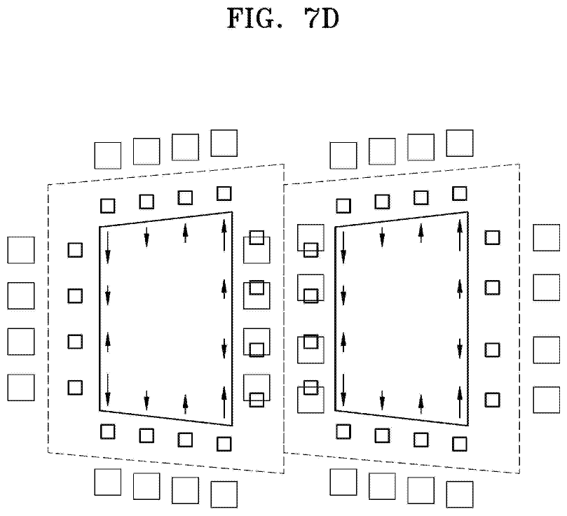

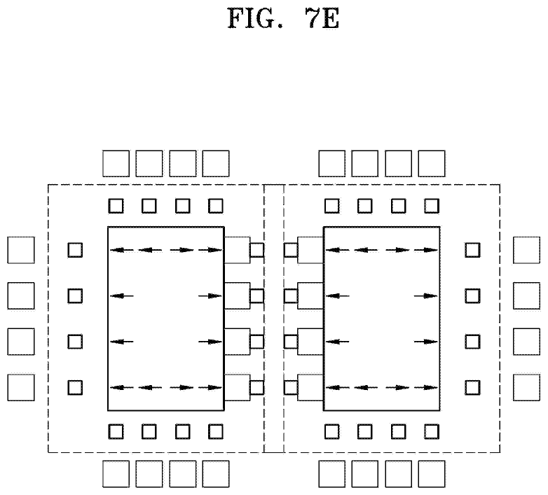

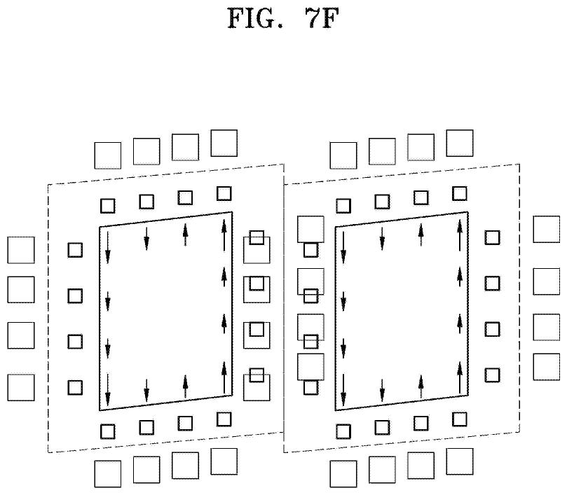

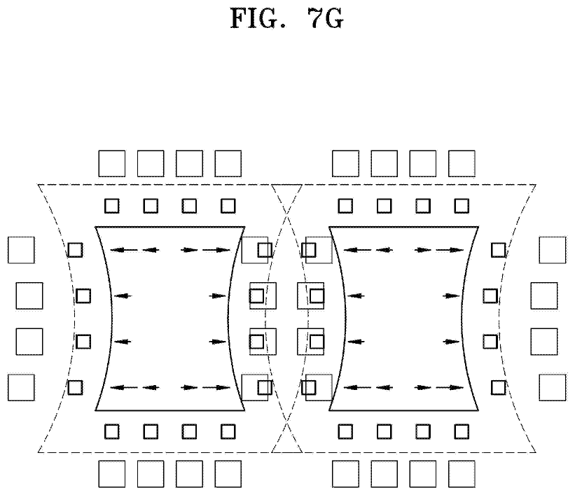

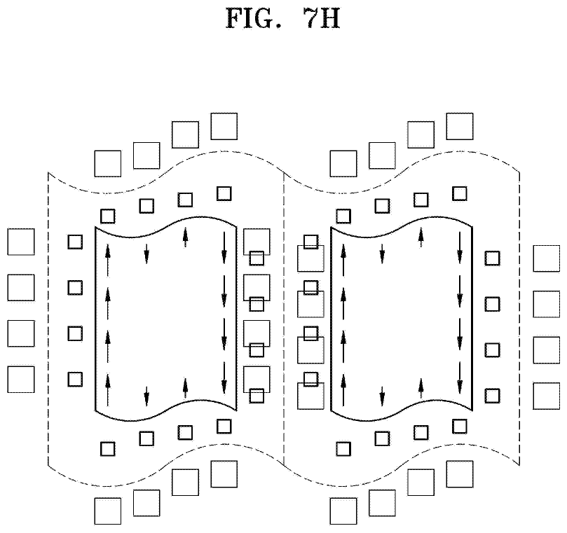

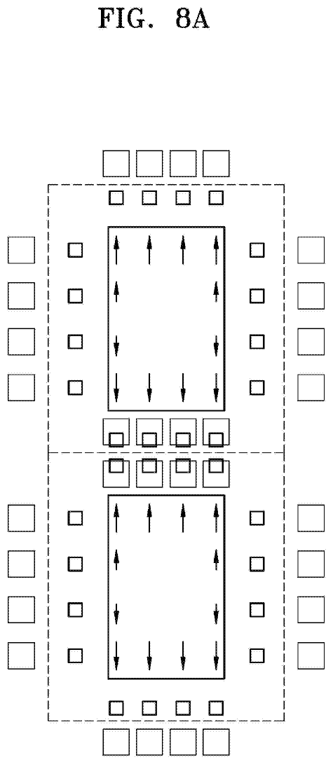

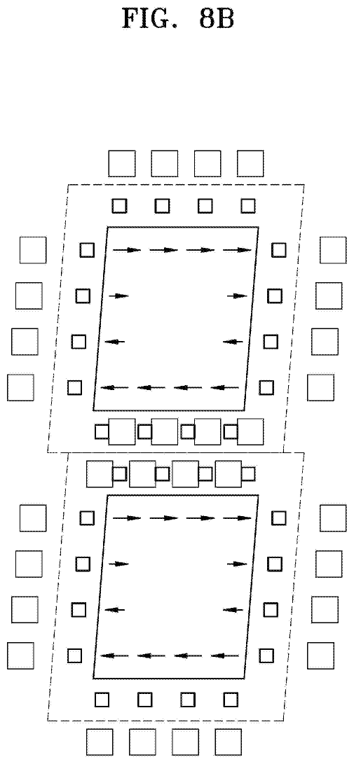

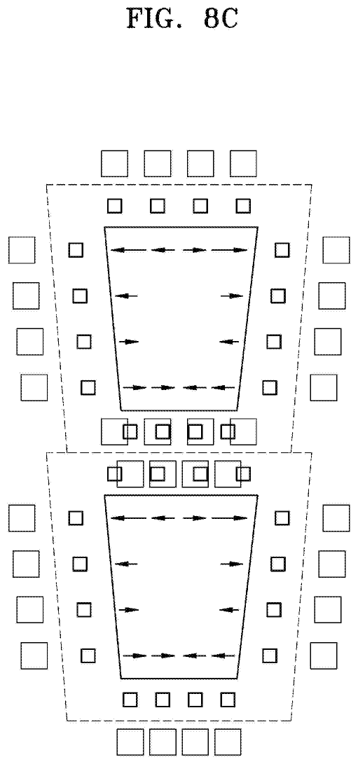

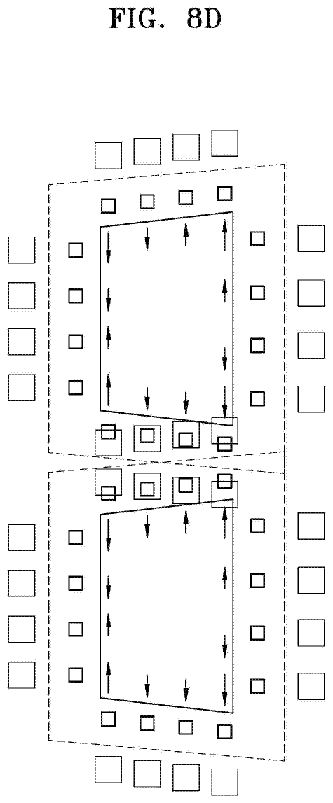

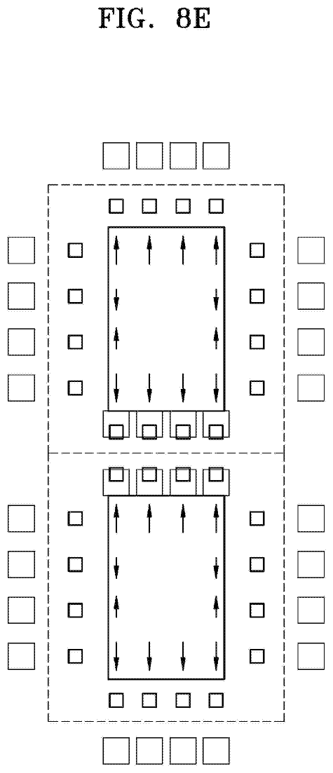

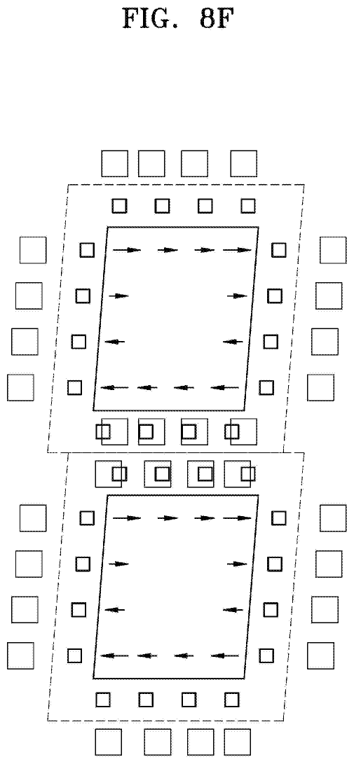

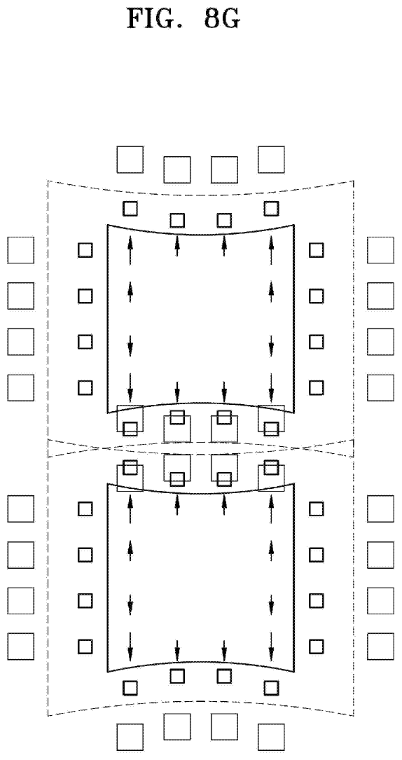

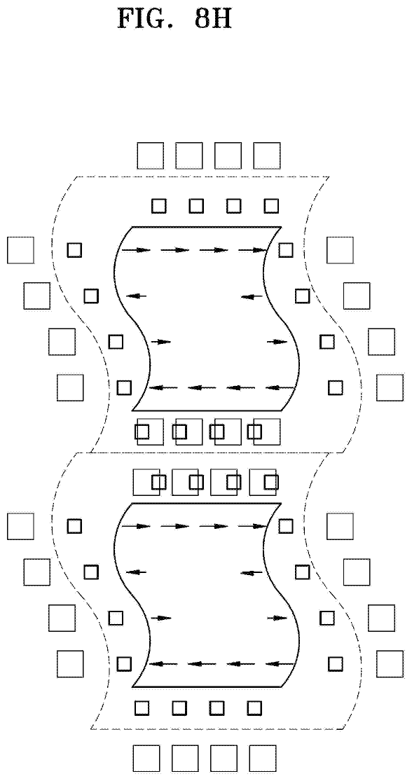

Therefore, when the main patterns of the first overlay mark of the first layer have been moved from an ideal reference position and it is not possible to know exactly how accurately the main patterns of the first overlay mark of the first layer have been moved through relative measurement, namely, components of the overlay of the first layer, in particular, high-order components, may not be calculated through relative measurement, the high-order components may not be corrected and remain without changes in a subsequent exposure process. As a result, when relative measurement is performed on the first overlay mark of the first layer, misalignment of the overlay due to the high-order components may increase as subsequent layers are stacked. Overlay components that may be calculated through relative measurement, for the first overlay mark of the first layer will be described in more detail in the description of FIGS. 7A through 8H.

In contrast, in the overlay correction method according to the present embodiment, all of the 2^{nd}-order or greater components of the overlay of the first layer, including the linear components, may be calculated by performing absolute measurement on the first overlay mark of the first layer. Therefore, the overlay in the subsequent exposure process may be accurately measured and corrected, leading to a great improvement in the overlay. In addition, by accurately measuring and correcting the overlay of the first layer, mismatching with subsequent exposure equipment may be reduced or minimized.

After the overlay components of the first layer are calculated, it is determined whether the overlay components of the first layer satisfy a set criterion (S134). When the set criterion is not satisfied (No), the overlay components of the first layer are input to exposure equipment (S136). In other words, components of exposure equipment that affect the overlay are controlled by inputting correction data corresponding to an overlay component to the exposure equipment. Subsequently, the first overlay mark is re-formed on the first layer by using the exposure equipment (S138). As described above, the overlay components may be removed or minimized in a subsequent exposure process, based on control of the components of the exposure equipment. In other words, the overlay of the first layer may be corrected. For reference, the control of the components of the exposure equipment may include control of a physical operation of a projection lens, a wafer stage, or a reticle stage.

On the other hand, when the set criterion is satisfied (Yes), the overlay correction method ends.

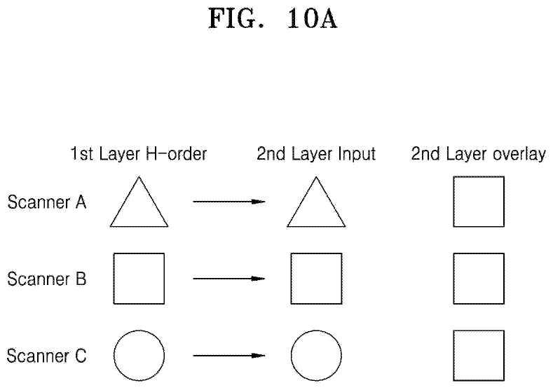

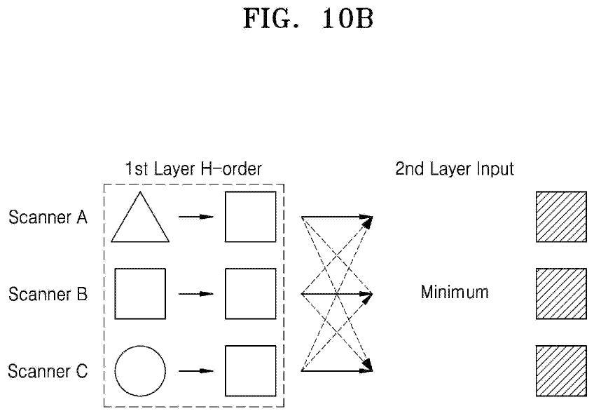

In the overlay correction method according to the present embodiment, all of the 2^{nd}-order or greater components including the linear components may be calculated by performing absolute measurement on the first overlay mark of the first layer. Therefore, the overlay in the subsequent exposure process may be accurately measured and corrected, leading to a great improvement in the overlay. In addition, mismatching with subsequent exposure equipment may be reduced or minimized by accurately measuring and correcting the overlay of the first layer, and thus, matching between exposure equipment in a current processing step and exposure equipment in a subsequent processing step may be improved. The current processing step may refer to an exposure process of the first layer. Minimization of mismatching between the exposure equipment of the current processing step and the subsequent processing step, or matching therebetween will be described in more detail in the description of FIGS. 10A and 10B.

FIGS. 3A and 3B are conceptual diagrams that illustrate a relative measurement and an absolute measurement used in overlay measurement in the overlay correction method of FIG. 1A. FIGS. 3A and 3B, an outermost dotted square conceptually represents a fixed area in an exposure process.

Referring to FIG. 3A, in the relative measurement, only relative positions of a main pattern MP and a vernier pattern VP of an overlay mark need to be measured, and thus there is no reference position. The center of the main pattern MP may correspond to a selected position, and the center of the vernier pattern VP may correspond to a measurement position. In FIG. 3A, an overlay Xol in the x direction may be expressed as Xol=(L−R)/2, and an overlay Yol in the y direction may be expressed as Yol=(U−D)/2. As described above, in the relative measurement, when the main pattern MP of a previous processing step has been moved from an original reference position, there is no way to check how much the main pattern MP of the previous processing step has been moved. Therefore, the magnitude of misalignment of the overlay due to the high-order components increases as the number of subsequent processing steps increases.

Referring to FIG. 3B, in the absolute measurement, a position of each of the main pattern MP and the vernier pattern VP is measured based on a reference position RP. The reference position RP is an absolute position regardless of a semiconductor substrate on which an overlay mark is formed, and may be a fixed position on a wafer stage or a fixed position on exposure equipment. Such absolute measurement may be performed by detecting a signal for a corresponding pattern and calculating a position through signal processing. In FIG. 3B, the reference position RP is indicated as a black dot on a center portion of the dotted square, which is the fixed area. This reference position RP may correspond to the fixed position. Accordingly, in FIG. 3B, an overlay Xol in the x direction may be expressed as Xol={an x coordinate x2 of a vernier pattern—a reference position x0 of an x axis}—{an x coordinate x1 of a main pattern—the reference position x0 of the x axis}. An overlay Yol in the y direction may be expressed as Yol={a y coordinate y2 of the vernier pattern—a reference position y0 of a y axis}—{a y coordinate y1 of the main pattern—the reference position y0 of the y axis}.

In the absolute measurement, measurement may be performed on one layer. In other words, in a method of performing an absolute measurement on the main pattern MP of a lower layer and performing an absolute measurement on the vernier pattern VP of an upper layer, the absolute measurements on the main pattern MP and the vernier pattern VP of an overlay mark may not be performed simultaneously, but instead may be performed separately in time. Even in the case of the overlay mark of the first layer, the absolute measurement may be performed separately on the main patterns and vernier patterns of the overlay mark formed on the first layer without being simultaneously performed. As such, in the case of the absolute measurement, because how much both the main pattern MP of the previous processing step and the vernier pattern VP of the current processing step have been moved from an absolute reference position are measured, even the high-order components of the overlay may be accurately calculated. In the case of the overlay of the first layer, the main pattern MP of the previous processing step may correspond to the main pattern of a first shot of the first layer, and the vernier pattern VP of the current processing step may correspond to the vernier pattern of a second shot of the first layer adjacent to the first shot. In addition, the main pattern MP of the previous processing step may correspond to the main pattern of the second shot of the first layer, and the vernier pattern VP of the current processing step may correspond to the main pattern of the first shot of the first layer.

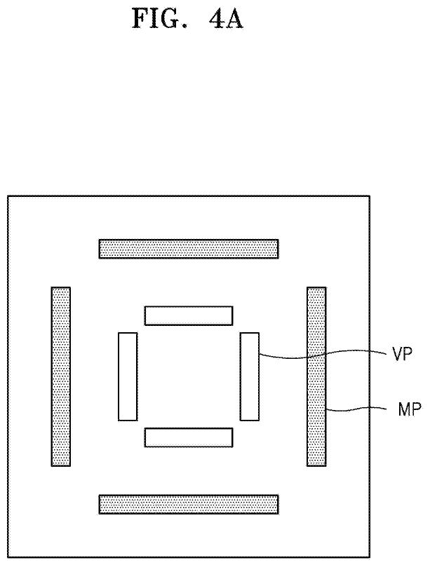

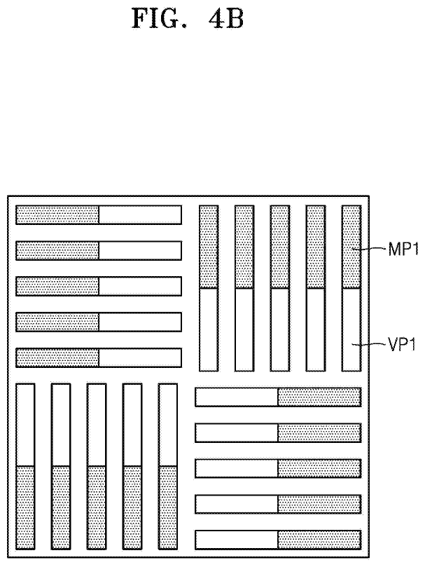

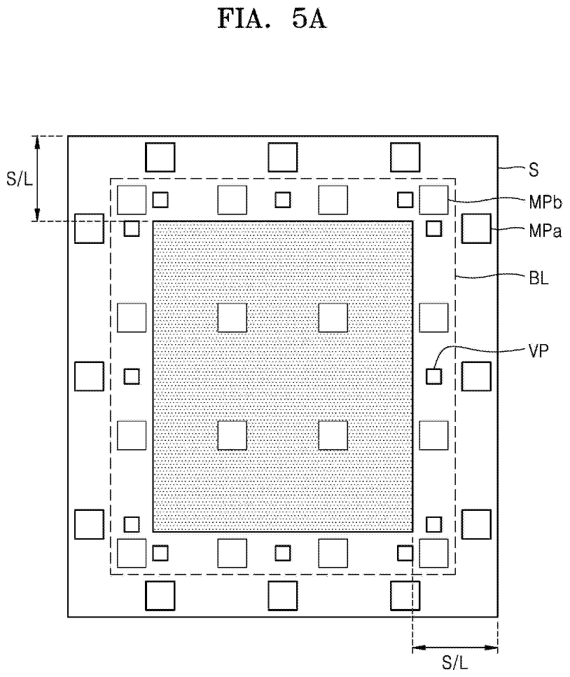

FIGS. 4A and 4B are plan views of a box in box (BIB) mark and an advanced image metrology (AIM) mark used in the overlay measurement in the overlay correction method of FIG. 1A.

FIG. 4A illustrates a BIB mark among overlay marks. Referring to FIG. 4A, a main pattern MP may be located outside, and a vernier pattern VP may be located inside. As described above, in the case of overlay measurement between a lower layer and an upper layer, a main pattern MP formed in the lower layer and a vernier pattern VP formed in the upper layer may be used in overlay measurement of the upper layer. In the case of the overlay measurement of the first layer, both the main pattern MP and the vernier pattern VP may be formed in the first layer and used in the overlay measurement of the first layer. A BIB mark formed in a first layer will be described in more detail in the description of FIGS. 5A and 5B. In FIG. 4A, each of the main pattern MP and the vernier pattern VP of the BIB mark may have a quadrangular shape having four line segments separated from each other. However, the shape of the BIB mark is not limited thereto.

FIG. 4B illustrates an AIM mark among overlay marks. Similar to FIG. 4A, in FIG. 4B, a main pattern MP1 may be located outside, and a vernier pattern VP1 may be located inside. Similar to the BIB mark, in the case of overlay measurement between a lower layer and an upper layer, a main pattern MP1 formed in the lower layer and a vernier pattern VP1 formed in the upper layer may be used in overlay measurement of the upper layer. In the case of the overlay measurement of the first layer, both the main pattern MP1 and the vernier pattern VP1 may be formed in the first layer and used in the overlay measurement of the first layer. An AIM mark formed in a first layer will be described in more detail in the description of FIGS. 6A and 5B. In FIG. 4B, each of the main pattern MP1 and the vernier pattern VP1 of the AIM mark may include four line & space patterns. However, the shape of the AIM mark is not limited thereto.

FIG. 5A is a plan view of BIB marks disposed in one shot of a first layer in which a pattern is initially formed on a semiconductor substrate, and FIG. 5B is a plan view of BIB marks disposed in shots adjacent to the first layer.

Referring to FIGS. 5A and 5B, FIG. 5A shows a form in which main patterns MPa and MPb and vernier patterns VP of BIB marks are disposed in one shot S of the first layer on the semiconductor substrate. In one shot S, a non-hatched portion of an outer portion of the shot S may correspond to a scribe lane S/L, and a hatched rectangular portion of the shot S may correspond to an inner portion of the shot S. A rectangular dotted line of a center portion of the scribe lane S/L in a width direction may correspond to a boundary line BL, which is a criterion for overlapping two adjacent shots S on each other. For example, as shown in FIG. 5B, when a second shot S2 is disposed adjacent to a first shot S1 in the x direction, respective boundary lines BL of the first shot S1 and the second shot S2 may overlap each other. Accordingly, a scribe lane S/L of the first shot S1 and a scribe lane S/L of the second shot S2 may overlap each other. A first main pattern MPa of the first shot S1 may overlap a vernier pattern VP of the second shot S2, and a first main pattern MPa of the second shot S2 may overlap a vernier pattern VP of the first shot S1. In FIG. 5A, three first main patterns MPa and three vernier patterns VP may be disposed on each of the sides of the boundary line BL of the one shot S.

For reference, the main patterns MPa and MPb disposed in the first layer may include a first main pattern MPa and a second main pattern MPb. The first main pattern MPa may correspond to a main pattern of a first overlay mark used for overlay measurement of the first layer, and may overlap a vernier pattern VP of a first overlay mark of a shot adjacent to the one shot S. The second main pattern MPb may correspond to a main pattern of a second overlay mark used for overlay measurement of the second layer, and may overlap a vernier pattern of a second overlay mark disposed in the second layer. As can be seen from FIG. 5A, the second main pattern MPb may be disposed not only in the scribe lane S/L of the outer portion of the shot S, but also in a scribe lane of the inner portion of the shot S. The second main pattern MPb of the scribe lane S/L of the outer portion of the shot S may not overlap with a vernier pattern VP of the shot adjacent to the shot S.

FIG. 5B shows an arrangement of first, second, and third shots S1, S2, and S3 adjacent to each other in the x and y directions, but a second main pattern is omitted for convenience of description. Four first main patterns MPa and four vernier patterns VP are disposed on each side of a boundary line BL. In more detail, two shots on both sides in the x direction with respect to the first shot S1 overlap each other on the basis of the boundary line BL, and two shots on both sides in the y direction overlap each other on the basis of the boundary line BL. In the case of the second shot S2, a left side in the x direction overlaps the first shot S1, based on the boundary line BL, a right side in the x direction does not overlap any other shot, and both sides in the y direction do not overlap any other shot. In the case of the third shot S3, both sides in the x direction do not overlap with other shots, an upper side in the y direction overlaps with the first shot S1, based on the boundary line BL, and a lower side does not overlap with any other shots. As the scribe lane S/L of an outer portion overlaps between adjacent shots as described above, a first main pattern MPa and a vernier pattern VP of the first overlay mark disposed in the overlapped scribe lanes S/L may overlap each other. Therefore, the overlay of the first layer may be calculated by absolute measurement and/or relative measurement on the first main pattern MPa and the vernier pattern VP of the first overlay mark.

FIG. 6A is a plan view of AIM marks disposed in one shot of a first layer in which a pattern is initially formed on a semiconductor substrate, and FIG. 6B is a plan view of AIM marks disposed in shots adjacent to the first layer.

Referring to FIGS. 6A and 6B, FIG. 6A shows a form in which main patterns MP1 and vernier patterns VP of AIM marks are disposed in one shot S of the first layer on the semiconductor substrate. In one shot S, a non-hatched portion of an outer portion of the shot S may correspond to a scribe lane S/L, and a hatched rectangular portion of the shot S may corresponds to an inner portion of the shot S. A rectangular dotted line of a center portion of the scribe lane S/L in a width direction may correspond to a boundary line BL, which is a criterion for overlapping two adjacent shots S on each other. For example, as shown in FIG. 6B, when a second shot S2 is disposed adjacent to a first shot S1 in the x direction, respective boundary lines BL of the first shot S1 and the second shot S2 may overlap each other. Accordingly, a scribe lane S/L of the first shot S1 and a scribe lane S/L of the second shot S2 may overlap each other. A main pattern MP1 of the first shot S1 may overlap a vernier pattern VP1 of the second shot S2, and a main pattern MP1 of the second shot S2 may overlap a vernier pattern VP1 of the first shot S1. In FIG. 6A, three main patterns MP1 and three vernier patterns VP may be disposed on each of the sides of the boundary line BL of the one shot S.

In addition, the main pattern MP1 of the AIM marks may correspond to a main pattern of a first overlay mark used for overlay measurement of the first layer. For example, the main pattern MP1 may correspond to the first main pattern MPa of FIG. 5A. Also, in the case of AIM marks, a main pattern of a second overlay mark used for overlay measurement of the second layer in the shot S of the first layer, namely, a main pattern corresponding to the second main pattern MPb of FIG. 5A, may be disposed. However, in FIG. 6A, the main pattern of the second overlay mark is omitted for convenience.

FIG. 6B shows shots arranged adjacent to each other in the x and y directions. In FIG. 6B, the main pattern of the second overlay mark is also omitted for convenience. Four main patterns MP1 and four vernier patterns VP1 are disposed on each side of a boundary line BL. The shapes of the first shot S1, the second shot S2, and the third shot S3 and an arrangement thereof may be substantially the same as the shapes of the first shot S1, the second shot S2, and the third shot S3 and the arrangement thereof described above with reference to FIG. 5B, except that the first overlay mark is an AIM mark. As a result, as the scribe lane of an outer portion overlap between adjacent shots, the main pattern MP1 and the vernier pattern VP1 of the first overlay mark, which is the AIM mark, disposed in the overlapped scribe lanes may overlap each other. Therefore, the overlay of the first layer may be calculated by absolute measurement and/or relative measurement on the main pattern MP1 and the vernier pattern VP1 of the first overlay mark, which is the AIM mark.

FIGS. 7A through 7H are conceptual views that illustrate components of a stitch overlay that may be calculated through relative measurement using shots adjacent to each other in the x direction.

Referring to FIGS. 7A and 7B, the overlay of the first layer, that is, the stitch overlay, may involve calculation of K3 and K6 components among linear components through relative measurement with respect to a first overlay mark in the shots adjacent to each other in the x direction. The K3 component may move in the x direction, that is, dx may be proportional to a slit position x in the x direction. Therefore, as shown in FIG. 7A, positions of main patterns and vernier patterns are misaligned from each other in the x direction in the shots adjacent to each other in the x direction, and thus, the K3 component may be calculated. The K6 component may move in the y direction, that is, dy may be proportional to the slit position x in the x direction. Therefore, as shown in FIG. 7B, positions of main patterns and vernier patterns are misaligned with each other in the y direction in the shots adjacent to each other in the x direction, and thus, the K6 component may be calculated.

In the case of K1 corresponding an offset in the x direction and K2 corresponding to an offset in the y direction, main patterns and vernier patterns move identically in the adjacent shots, and thus no misalignment occurs. Also, in the case of K4 and K5 components, dy and dx are proportional to a scan position y in the y direction, and thus no misalignment between the main patterns and the vernier patterns in the shots adjacent to each other in the x direction. Therefore, the K1, K2, K4, and K5 components may not even be calculated through relative measurement.

Referring to FIGS. 7C and 7D, the overlay of the first layer may involve calculation of K9 and K10 components among 2^{nd}-order components, through relative measurement with respect to the first overlay mark in the shots adjacent to each other in the x direction. The dx of the K9 component may be proportional to both the slit position x in the x direction and the scan position y in the y direction. Therefore, as shown in FIG. 7C, positions of main patterns and vernier patterns are misaligned with each other in the x direction in the shots adjacent to each other in the x direction, and thus, the K9 component may be calculated. The dy of the K10 component may also be proportional to both the slit position x in the x direction and the scan position y in the y direction. Therefore, as shown in FIG. 7D, positions of main patterns and vernier patterns are misaligned with each other in the y direction in the shots adjacent to each other in the x direction, and thus, the K10 component may be calculated.

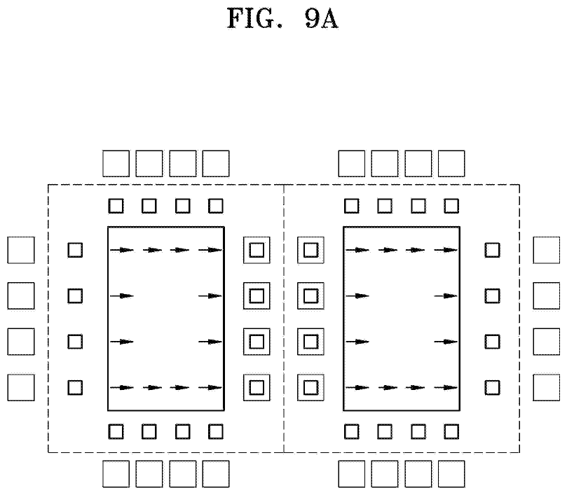

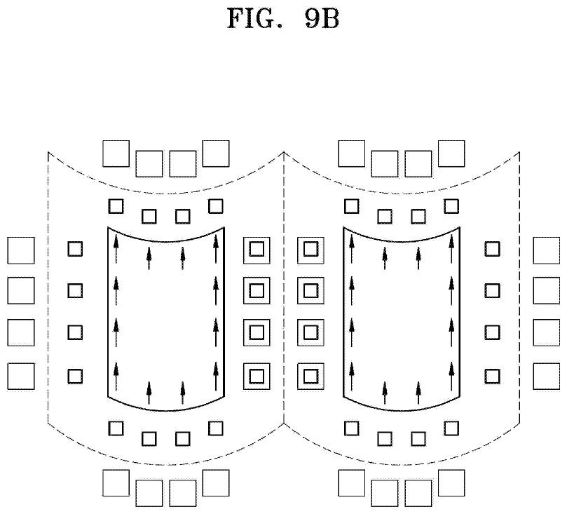

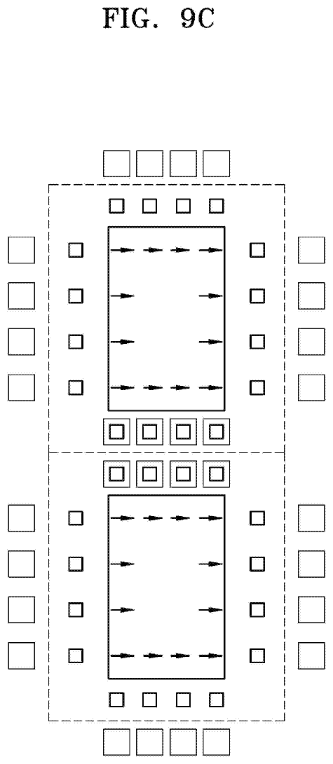

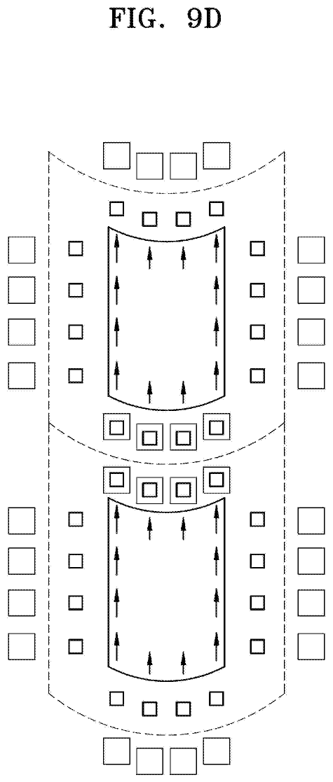

K7 where dx is proportional to the square of the slit position x in the x direction and K11 where dx is proportional to the square of the scan position y in the y direction are not misaligned with each other. K8 where dy is proportional to the square of the scan position y in the y direction and K12 where dy is proportional to the square of the slit position x in the x direction are also not misaligned with each other. Therefore, the K7, K8, K11, and K12 components may not even be calculated through relative measurement. The cases of K7 and K12 related to the shots adjacent to each other in the x direction will be described in more detail with reference to FIGS. 9A and 9B.

Referring to FIGS. 7E through 7H, the overlay of the first layer may involve calculation of K16 and K17 components among 3^{rd}-order components, through relative measurement with respect to the first overlay mark in the shots adjacent to each other in the x direction. The dy of the K16 component may be proportional to both the slit position x in the x direction and the square of the scan position y in the y direction. Therefore, as shown in FIG. 7F, degrees to which the positions of main patterns and vernier patterns are misaligned from each other in the x direction and the y direction in the shots adjacent to each other in the x direction may be changed, and thus, the K16 component may be calculated. The dx of the K17 component may also be proportional to both the slit position x in the x direction and the square of the scan position y in the y direction. Therefore, as shown in FIG. 7G, degrees to which the positions of main patterns and vernier patterns are misaligned from each other in the x direction and the y direction in the shots adjacent to each other in the x direction may be changed, and thus, the K17 component may be calculated.

K13 and K20 components in which dx and dy are proportional to the cube of the slit position x in the x direction may be theoretically calculated, but may not be accurately calculated in practice. For example, as shown in FIG. 7E, the positions of the main patterns and the vernier patterns may be misaligned with each other in the x direction in the shots adjacent to each other in the x direction, and, as shown in FIG. 7H, the positions of the main patterns and the vernier patterns may be misaligned with each other in the y direction in the shots adjacent to each other in the x direction. In other words, because the misalignment direction of K13 is similar to that of K3 and the misalignment direction of K20 is similar to that of K6, but the misalignment degree is proportional to the cube of the slit position x, calculation of the K13 and K20 components may be difficult or impossible.

K14 and K19, in which dy and dx are proportional to the cube of the scan position y in the y direction, and K15 and K18, in which dx and dy are proportional to both the square of the slit position x in the x direction and the scan position y in the y direction, may not be calculated through relative measurement, because a misalignment between the main patterns and the vernier patterns does not occur in the shots adjacent to each other in the x direction.

To sum up, in the case of the overlay of the first layer, components proportional to the slit position x in the x direction may be calculated through relative measurement. Components proportional to the cube of the slit position x may be theoretically calculated, but may be infrequently calculated in practice. The other components may not be calculated through relative measurement. However, in the case of the overlay correction method according to the present embodiment, all components of the overlay including high-order components may be calculated based on absolute measurement.

FIGS. 8A through 8H are conceptual views that illustrate components of a stitch overlay that may be calculated through relative measurement using shots adjacent to each other in the y direction.

Referring to FIGS. 8A through 8H, when the shots adjacent to each other in the y-direction are used, a similar concept to the case of using the shots adjacent to each other in the x-direction in FIGS. 7A through 7H may be applied. For example, in the case of the overlay of the first layer, components proportional to the scan position y in the y direction may be calculated through relative measurement with respect to a first overlay mark within the shots adjacent to each other in the y direction. Components proportional to the cube of the scan position y may be theoretically calculated, but may be infrequently calculated in practice. The other components may not be calculated through relative measurement. Accordingly, when the shots adjacent to each other in the y direction are used, K4, K6, K9, K10, K15, and K16 may be calculated through relative measurement, K14 and K19 may be calculated theoretically but may be infrequently calculated in practice, and K1 through K3, K6 through K8, K11 through K13, K16, K17, and K20 may not be calculated. The cases of K7 and K12 related to the shots adjacent to each other in the y direction will be described in more detail with reference to FIGS. 9C and 9D.

As a result, in the case of the overlay of the first layer, K3 through K6, K9, K10, and K15 through K18 may be calculated through relative measurement using the shots adjacent to each other in the x direction and the shots adjacent to each other in the y direction, K13, K14, K19, and K20 may be calculated theoretically but may be infrequently calculated in practice, and the rest K1, K2, K7, K8, K11, and K12 may not be calculated. However, in the overlay correction method according to the present embodiment, because absolute measurement is used, all of the components of the overlay of the first layer, including high-order components K7, K8, K11, and K12, may be accurately calculated.

FIGS. 9A through 9D are conceptual views that illustrate representative components that may not be calculated through relative measurement using the shots adjacent to each other in the x direction and the y direction.

Referring to FIGS. 9A through 9D, in the case of DUV exposure equipment among exposure equipment, parameters of K7 and 2^{nd}-order components of K12 may greatly affect an overall overlay. For reference, an overall overlay Xo in the x direction may be expressed as Xo=K1+K3*x+K5*y+K7*x²+K9*xy+K11*y²+K13*x³+K15*x²y+K17*xy²+K19*y³+ and an overall overlay Yo in the Y direction may be expressed as Yo=K2+K4*y+K6*x+K8*y²+K10*xy+K12*x²+K14*y³+K16*xy²+K18*x²y+K20*x³+g. F may refer to the remaining 4th-order or greater overlay components.

The dx of the K7 component may be proportional to the square of the slit position x in the x direction. Accordingly, as can be seen through FIG. 9A, because movements in the x direction from the center to both sides in the x direction are the same as each other, there is no misalignment between the shots adjacent to each other in the x direction. As can be seen through FIG. 9C, the shots adjacent to each other in the y direction do not affect the K7 component at all. Therefore, the K7 component may not be calculated through the shots adjacent to each other in the x and y directions.

The dy of the K12 component may be proportional to the square of the slit position x in the x direction. Thus, as shown in FIG. 9B, the shots adjacent to each other in the x direction do not affect the K12 component. As can be seen through FIG. 9D, because movements in the y direction from the center to both sides in the x direction are the same as each other, there is no misalignment between the shots adjacent to each other in the y direction. Therefore, the K12 component may not be calculated through the shots adjacent to each other in the x and y directions.

However, in the overlay correction method according to the present embodiment, because absolute measurement is used, the K7 and K12 components of the overlay may be accurately calculated, and therefore, the overlay may be greatly improved in an exposure process by exposure equipment, particularly, DUV exposure equipment.

FIGS. 10A and 10B are conceptual diagrams illustrating matching between exposure equipment generated in an overlay correction method using relative measurement according to a comparative example and the overlay correction method using absolute measurement according to an example embodiment.

Referring to FIG. 10A, in the overlay correction method using relative measurement according to the comparative example, overlay marks are formed in a first layer through three different exposure equipment, e.g., scanners A, B, and C, and the overlay of the first layer is calculated through relative measurement. At least one of the scanners A, B, and C may be an EUV scanner, and the others may be different types of DUV scanners. However, the types of scanners A, B, and C are not limited to the aforementioned scanners.

In FIG. 10A, when it is assumed that triangles and circles represent high-order components of overlay and squares represent a state in which there are no high-order components of overlay, high-order components of overlay may not be calculated through relative measurement with respect to the overlay marks of the first layer. Accordingly, because the high-order components of the overlay of the first layer may not be corrected, data including the high-order components of the overlay without changes is input to exposure equipment in an exposure process of a subsequent layer, for example, the second layer. Therefore, even when the overlay is calculated through relative measurement in the second layer and the high-order components of the overlay of the second layer are corrected as shown in the squares on the right side, the high-order components of the overlay of the first layer may be maintained without being corrected. As a result, the high-order components of the overlay of the first layer may be maintained as the overlays of subsequent layers, and the size of the overlay may increase in a direction of an ascending order of layers.

To reduce or minimize a problem of relative measurement with respect to the overlay marks of the first layer, the exposure equipment of the first layer and its subsequent layer may be kept the same, as shown by solid arrows in FIG. 10A, because, in general, when exposure equipment of the first layer and its subsequent layers are different from each other, misalignment of the subsequent layers may be further increased due to the overlay of the first layer. As a result, in the overlay correction method using relative measurement according to a comparative example, mis-matching between the exposure equipment of the first layer and the exposure equipment of its subsequent layer is large, and therefore, matching accuracy may be very low.

Referring to FIG. 10B, in the overlay correction method using absolute measurement according to the present embodiment, overlay marks are formed in the first layer through three different items of exposure equipment, e.g., scanners A, B, and C, and the overlay of the first layer is calculated through absolute measurement. At least one of the scanners A, B, and C may be an EUV scanner, and the others may be different types of DUV scanners. However, the types of scanners A, B, and C are not limited to the aforementioned scanners.

In FIG. 10B, when it is assumed that triangles and circles represent high-order components of overlay and squares represent a state in which there are no high-order components of overlay, high-order components of overlay may be all calculated through absolute measurement with respect to the overlay marks of the first layer. Accordingly, as shown on the right side of a dotted square, all of the high-order components of the overlay of the first layer may be all corrected into squares, and, in an exposure process of its subsequent layer, for example, the second layer, data from which the high-order components of the overlay has been minimized or removed may be input to exposure equipment. Based on the data from which the high-order components of the overlay has been minimized or removed, the overlay is calculated and corrected through relative measurement and/or absolute measurement in the second layer, so that the high-order components of the overlay of the second layer may be corrected to be reduced or minimized as shown in the squares on the right side. Consequently, by minimizing or removing the high-order components of the overlay of the first layer through absolute measurement with respect to the overlay mark of the first layer, the high-order components of the overlay may be all minimized or removed in all subsequent layers.

As the high-order components of the overlay of the first layer are minimized or removed through absolute measurement with respect to the overlay mark of the first layer, exposure equipment of the first layer and its subsequent layer, for example, the second layer, may be maintained the same as indicated by the solid arrows in FIG. 10B, and there may be no problem at all even when the exposure equipment for the first layer and the second layer are different from each other as shown by dotted arrows. As a result, in the overlay correction method using absolute measurement according to the present embodiment, mis-matching between the exposure equipment of the first layer and the exposure equipment of its subsequent layer may be reduced or minimized, and therefore, matching accuracy may be greatly improved.

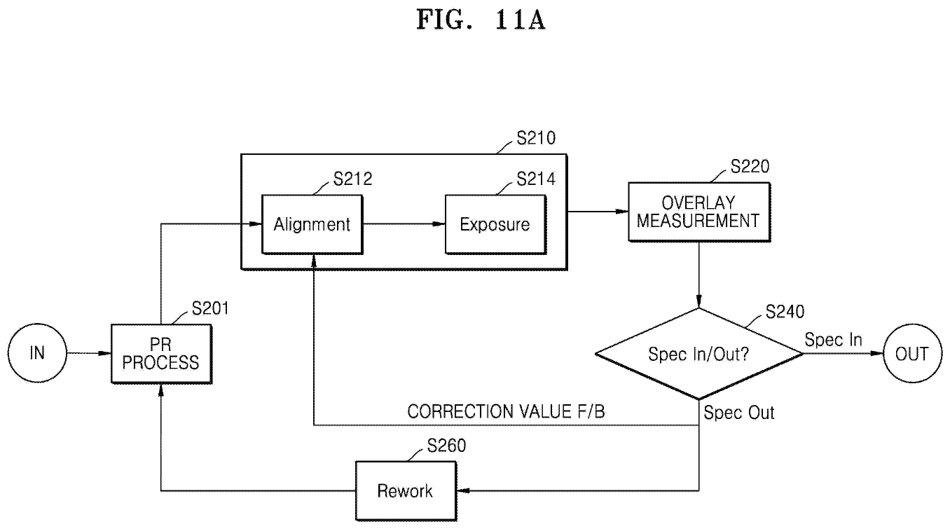

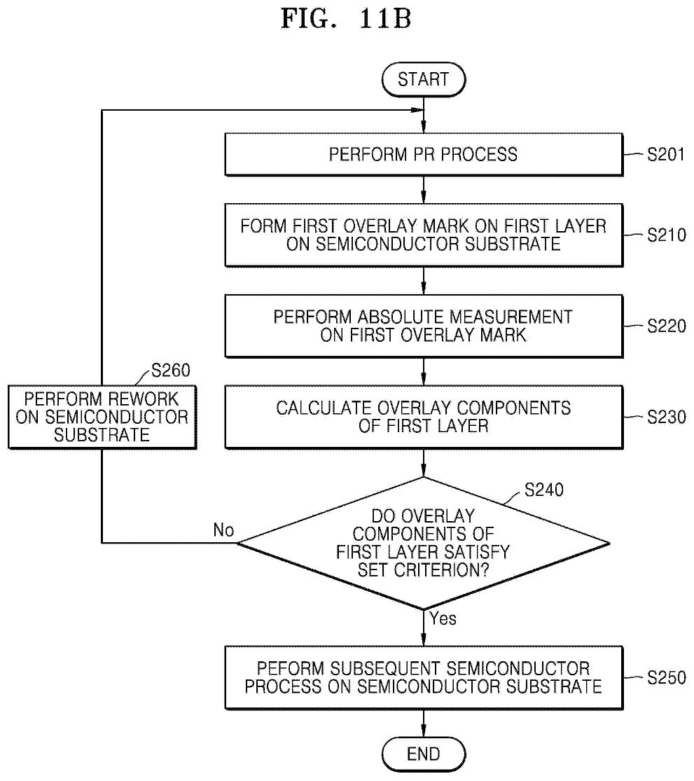

FIG. 11A is a conceptual diagram that illustrates a semiconductor device manufacturing method including an overlay correction method according to an embodiment, and FIG. 11B is a flowchart of the semiconductor device manufacturing method of FIG. 11A. Descriptions of FIGS. 11A and 11B which are the same as those of FIGS. 1A through 10B are given briefly or omitted herein.

Referring to FIGS. 11A and 11B, in the semiconductor device manufacturing method including the overlay correction method according to the present embodiment (hereinafter, simply referred to as a ‘semiconductor device manufacturing method’), a photoresist (PR) process is first performed (S201). The PR process may refer to a process of forming a PR layer on a semiconductor substrate to pattern a first layer of the semiconductor substrate. The PR layer may be formed through, for example, spin coating equipment.

Then, a first overlay mark is formed on the first layer on the semiconductor substrate (S210). Operation S210 of forming the first overlay mark may include an alignment operation S212 and an exposure operation S214, as can be seen through FIG. 11A. In the aligning operation S212, the semiconductor substrate may be put into an exposure equipment and aligned within the exposure equipment. In the aligning operation S212, components of the exposure equipment may be controlled so that an overlay does not occur by inputting correction values for the components of the overlay. The control of the components of exposure equipment may include control of a physical operation of a projection lens, a wafer stage, or a reticle stage. In the exposure operation S214, light may be radiated to the PR layer on the semiconductor substrate through a reticle and an optical system. The exposure operation S214 may refer to forming a PR pattern on the semiconductor substrate by including developing, baking, cleaning, and the like. Operation S210 of forming the first overlay mark may be substantially the same as operation S110 of forming the first overlay mark, in the overlay correction method of FIG. 1A.

Thereafter, absolute measurement is performed on the first overlay mark (S220). Operation S220 of performing absolute measurement on the first overlay mark may be substantially the same as operation S220 of performing absolute measurement on the first overlay mark, in the overlay correction method of FIG. 1A. In operation S220 of performing absolute measurement on the first overlay mark, relative measurement with respect to the first overlay mark may also be performed.

Subsequently, overlay components of the first layer are calculated (S230). In FIG. 11A, operation S230 of calculating the overlay components of the first layer is not shown. Operation S230 of calculating the overlay components of the first layer may be substantially the same as operation S132 of calculating the overlay components of the first layer, in the overlay correction operation S130 of the first layer of FIG. 1B. In the semiconductor device manufacturing method according to the present embodiment, all of the overlay components of the first layer, e.g., K1 through K20 overlay parameters, may be calculated by performing absolute measurement on the first overlay mark.

Then, it is determined whether the overlay components of the first layer satisfy a set criterion (S240). Operation S240 of determining whether the overlay components of the first layer satisfy a set criterion may be substantially the same as operation S134 of determining whether the overlay components of the first layer satisfy the set criterion, in the overlay correction operation S130 of the first layer of FIG. 1B. In FIG. 11A, Spec In may refer to a case in which a criterion is satisfied (Yes), and Spec Out may refer to a case in which the criterion is not satisfied (No).

When the criterion is satisfied (Yes), a subsequent semiconductor process is performed on the semiconductor substrate (S250). In FIG. 11A, ‘IN’ on the left side means that the semiconductor substrate is input into the exposure equipment, and ‘OUT’ on the right side means that the semiconductor substrate is discharged from the exposure equipment, and then a subsequent semiconductor process is performed on the semiconductor substrate. The subsequent semiconductor process may include various processes. For example, the subsequent semiconductor process may include a deposition process, an etching process, an ion process, and a cleaning process. The subsequent semiconductor process may also include a singulation process of individualizing a semiconductor substrate in the form of a wafer into individual semiconductor chips, a test process of testing the semiconductor chips, and a packaging process of packaging the semiconductor chips. A semiconductor device may be completed through the subsequent semiconductor process for the semiconductor substrate.

In the subsequent semiconductor process, an exposure process may be performed on upper layers positioned over the first layer. In an exposure process for these upper layers, overlay correction may be performed through measurement of overlay marks. For the measurement of overlay marks in the upper layers, an absolute measurement method and/or a relative measurement method may be used. In addition, the measurement of the overlay mark may measure the main pattern of a lower layer and the vernier pattern of an upper layer.

When the criterion is not satisfied (No), the overlay components of the first layer are input to exposure equipment, and rework is performed on the semiconductor substrate (S260). The rework may refer to removing the PR layer including an existing first overlay mark on the semiconductor substrate. In FIG. 11A, a process of inputting the overlay components of the first layer to the exposure equipment is indicated by a ‘correction value F/B’ arrow. The process of inputting the overlay components of the first layer to the exposure equipment may be substantially the same as operation S136 of inputting the overlay components of the first layer to the exposure equipment in the overlay correction operation S130 of the first layer of FIG. 1B.

After the rework, the method proceeds to operation S201 of performing a PR process, thereby forming a PR layer on the semiconductor substrate, and a first overlay mark is formed on the first layer on the semiconductor substrate (S210). Operation S201 of performing the PR process after the rework, and operation S210 of forming the first overlay mark on the first layer may be substantially the same as operation S138 of reforming the overlay mark of the first layer, in the overlay correction operation S130 of the first layer of FIG. 1B.

While the inventive concept has been particularly shown and described with reference to embodiments thereof, it will be understood that various changes in form and details may be made therein without departing from the spirit and scope of the following claims.

What is claimed is:

1. An overlay correction method comprising:
forming a first overlay mark on a first layer on which a pattern is initially formed on a semiconductor substrate;
performing an absolute measurement on the first overlay mark; and
correcting an overlay of the first layer based on the absolute measurement,
wherein the absolute measurement is a measurement method based on a fixed position of exposure equipment used to form the first overlay mark.

2. The overlay correction method of claim 1, wherein
the first overlay mark comprises an outer mark and an inner mark formed on the first layer,
the overlay of the first layer is a stitch overlay between adjacent shots, and
wherein performing the absolute measurement comprises:
performing an absolute measurement on the outer mark; and
performing an absolute measurement on the inner mark,
wherein performing the absolute measurement on the outer mark and performing the absolute measurement on the inner mark are spaced apart in time.

3. The overlay correction method of claim 2, wherein
a scribe lane is arranged on an outer portion of one shot area,
the scribe lane is classified as an external scribe lane or an internal scribe lane based on a central boundary line,
the outer mark is disposed on the external scribe lane and the inner mark is disposed on the internal scribe lane, and
in the forming of the first overlay mark, respective scribe lanes of two adjacent shots overlap each other based on the central boundary line, and the outer mark of a first shot and the inner mark of a second shot adjacent to the first shot overlap each other, and the inner mark of the first shot and the outer mark of the second shot overlap each other.

4. The overlay correction method of claim 1, wherein the first overlay mark is a box in box (BIB) mark or an advanced image metrology (AIM) mark.

5. The overlay correction method of claim 1, wherein second order or higher components of the overlay of the first layer are calculated through the absolute measurement.

6. The overlay correction method of claim 5, wherein
when a direction in which a slit extends in an exposure process is a first direction, and a scanning direction perpendicular to the first direction is a second direction,
the second order or higher components comprise a K7 component whose movement in the first direction is proportional to a square of a slit position in the first direction, and a K12 component whose movement in the second direction is proportional to a square of the slit position in the first direction.

7. The overlay correction method of claim 1, wherein
the correcting of the overlay of the first layer comprises:
calculating components of the overlay of the first layer based on the absolute measurement;
determining whether the components of the overlay of the first layer satisfy a set criterion;
when the set criterion is not satisfied, inputting the components of the overlay of the first layer to exposure equipment; and
re-forming the first overlay mark on the first layer by using the exposure equipment, and
when the set criterion is satisfied, the overlay correction method is terminated.

8. The overlay correction method of claim 1, wherein
the first overlay mark comprises an outer mark and an inner mark formed on the first layer,
performing the absolute measurement comprises performing a relative measurement, and
in the relative measurement, a relative position between the outer mark of a first shot and the inner mark of a second shot adjacent to the first shot or a relative position between the inner mark of the first shot and the outer mark of the second shot is measured.

9. The overlay correction method of claim 1, wherein
first exposure equipment for forming the first overlay mark is different from second exposure equipment for forming a second overlay mark on a second layer positioned over the first layer, and
second order or higher components of the overlay of the first layer are corrected based on the absolute measurement.

10. The overlay correction method of claim 9, wherein
the first exposure equipment is deep ultraviolet (DUV) exposure equipment, and the second exposure equipment is extreme ultraviolet (EUV) exposure equipment, or
the first exposure equipment is EUV exposure equipment, and the second exposure equipment is DUV exposure equipment.

11. An overlay correction method comprising:
forming, by using first exposure equipment, a first overlay mark on a first layer on which a pattern is initially formed on a semiconductor substrate;
performing an absolute measurement on the first overlay mark;
calculating components of an overlay of the first layer based on the absolute measurement;
determining whether the components of the overlay of the first layer satisfy a set criterion;
when the set criterion is not satisfied, inputting the components of the overlay of the first layer to the first exposure equipment; and
re-forming the first overlay mark on the semiconductor substrate by using the first exposure equipment,
wherein
the first overlay mark comprises an outer mark and an inner mark formed on the first layer, and
wherein performing the absolute measurement comprises:
performing absolute measurements on the outer mark and the inner mark separately.

12. The overlay correction method of claim 11, wherein
performing the absolute measurement comprises performing a relative measurement, and
the absolute measurement is a measurement method based on a fixed position of the first exposure equipment,
performing the relative measurement comprises measuring a relative position between the outer mark and the inner mark, and
the absolute measurement and the relative measurement are performed on two adjacent shots in the first layer.

13. The overlay correction method of claim 11, wherein
a scribe lane is arranged on an outer portion of one shot area, and
in the forming of the first overlay mark, respective scribe lanes of two adjacent shots overlap each other, and
the outer mark of a first shot and the inner mark of a second shot adjacent to the first shot overlap each other and the inner mark of the first shot and the outer mark of the second shot overlap each other.

14. The overlay correction method of claim 11, wherein
second order or higher components of the overlay of the first layer are calculated through the absolute measurement,
when a direction in which a slit extends in an exposure process is a first direction, and a scanning direction perpendicular to the first direction is a second direction, and
the second order or higher components comprise a K7 component whose movement in the first direction is proportional to a square of a slit position in the first direction, and a K12 component whose movement in the second direction is proportional to a square of the slit position in the first direction.

15. A semiconductor device manufacturing method comprising:
forming, by using first exposure equipment, a first overlay mark on a first layer on which a pattern is initially formed on a semiconductor substrate;
performing an absolute measurement on the first overlay mark;
calculating an overlay of the first layer based on the absolute measurement;
determining whether the overlay of the first layer satisfies a set criterion; and
when the set criterion is satisfied, performing a subsequent semiconductor process,
when the set criterion is not satisfied, data about the overlay of the first layer is input to the first exposure equipment, the method further comprising re-forming the first overlay mark,
wherein the absolute measurement is a measurement method based on a fixed position of the first exposure equipment.

16. The semiconductor device manufacturing method of claim 15, wherein
the first overlay mark comprises an outer mark and an inner mark formed on the first layer,
performing of the absolute measurement comprises performing a relative measurement,
the absolute measurement measures a position of each of the outer mark and the inner mark based on the fixed position,
the relative measurement measures a relative position between the outer mark and the inner mark, and
the absolute measurement and the relative measurement are performed on two adjacent shots in the first layer.

17. The semiconductor device manufacturing method of claim 15, wherein
when the set criterion is not satisfied, a photo-resist (PR) on the semiconductor substrate is removed and is re-formed on the semiconductor substrate, and the first overlay mark is re-formed on the first layer by using the first exposure equipment.

18. The semiconductor device manufacturing method of claim 15, wherein
the first overlay mark comprises an outer mark and an inner mark formed on the first layer,
a scribe lane is arranged on an outer portion of one shot area,
the inner mark is disposed on an inner portion of the scribe lane, and the outer mark is disposed on an outer portion of the scribe lane, and
in the forming of the first overlay mark, respective scribe lanes of two adjacent shots on outer portions of the two adjacent shots overlap each other, and the outer mark of a first shot and the inner mark of a second shot adjacent to the first shot overlap each other and the inner mark of the first shot and the outer mark of the second shot overlap each other.

19. The semiconductor device manufacturing method of claim 15, wherein
second order or higher components of the overlay of the first layer are calculated through the absolute measurement,
when a direction in which a slit extends in an exposure process is a first direction, and a scanning direction perpendicular to the first direction is a second direction,
the second order or higher components comprise a K7 component whose movement in the first direction is proportional to a square of a slit position in the first direction, and a K12 component whose movement in the second direction is proportional to a square of the slit position in the first direction.

20. The semiconductor device manufacturing method of claim 15, wherein
the first exposure equipment is different from second exposure equipment for forming a second overlay mark on a second layer positioned over the first layer, and
second order or higher components of the overlay of the first layer are corrected based on the absolute measurement.
